(19) United States
(12) Patent Application Publication
(10) Pub. No.: US 2008/0256153 A1
(43) Pub. Date: Oct. 16, 2008

(54) RANDOM NUMBER SIGNAL GENERATOR USING PULSE OSCILLATOR

(76) Inventors: Ji Man PARK, Daejeon (KR); Young Soo PARK, Daejeon (KR); Sung Ik JUN, Daejeon (KR); Young Sae KIM, Daejeon (KR); Moo Seop KIM, Daejeon (KR); Hong Il JU, Daejeon (KR); Young Soo KIM, Daejeon (KR); Su Gil CHOI, Daejeon (KR)

Correspondence Address: LADAS & PARRY LLP, 224 SOUTH MICHIGAN AVENUE, SUITE 1600, CHICAGO, IL, 60604, US

(21) Appl. No.: 12/055,674

(22) Filed: Mar. 26, 2008

(30) Foreign Application Priority Data
Apr. 13, 2007 (KR) 10-2007-0036328
Jul. 20, 2007 (KR) 10-2007-0073060

(51) Int. Cl. G06F 7/58; H03B 29/00; H03K 3/03

(52) U.S. Cl. 708/251; 331/46; 331/57

(57) ABSTRACT

A random number signal generator using pulse oscillators, the generator including: a first pulse oscillator oscillating a first pulse at high speed; a second pulse oscillator oscillating a second pulse; a sampler receiving an output pulse of the first oscillator as data, receiving an output pulse of the second pulse oscillator as a clock signal, and outputting a plurality of output signals; and a digital processor generating a random number signal with a desired size by using the output signals of the sampler.

### CROSS-REFERENCE TO RELATED APPLICATIONS

This application claims the priorities of Korean Patent Applications Nos. 2007-0036328 filed on Apr. 13, 2007 and 2007-0073060 filed on Jul. 20, 2007 in the Korean Intellectual Property Office, the disclosures of which are incorporated herein by references.

### BACKGROUND OF THE INVENTION

1. Field of the Invention

The present invention relates to a pulse oscillator, and more particularly, to a random number signal generator using a pulse oscillator.

This work was partly supported by the IT R&D program of MIC/IITA [2006-S-041-01, Development of a Common Security Core Module for supporting secure and trusted service in the next generation mobile terminals].

2. Description of the Related Art

In general, when noise is generated using a thermal noise device at an input terminal of an operation amplifier, the generated noise is amplified, the amplified noise is compared with an arbitrary reference voltage, and an output pulse is generated.

Also, there are apparatuses generating a pulse by amplifying the noise. However, since the noise has a very small signal voltage, a circuit becomes complicated to amplify the noise, thereby increasing power consumption and an area thereof.

### SUMMARY OF THE INVENTION

An aspect of the present invention provides a random number signal generator using a pulse oscillator, the generator including a simple circuit, using two pulse oscillators with small power and a small area, and controlling speed of outputting data by controlling the size of a resistor.

According to an aspect of the present invention, there is provided a random number signal generator using pulse oscillators, the generator including: a first pulse oscillator oscillating a first pulse at high speed; a second pulse oscillator oscillating a second pulse; a sampler receiving an output pulse of the first oscillator as data, receiving an output pulse of the second pulse oscillator as a clock signal, and outputting a plurality of output signals; and a digital processor generating a random number signal with a desired size by using the output signals of the sampler.

The generator may further include a variable resistor to provide a shake to a waveform of the output pulse of the second pulse oscillator.

As described above, the present invention provides a random number signal generator generating a random pulse using two pulse oscillators and a sampler and generating a random number using a digital processor. The generator may be embodied as a simple circuit with small power and a small area. It is easy to embody the generator as a chip. The generator may be applied as oscillators of various types.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a block diagram illustrating a configuration of a random number signal generator using pulse oscillators according to an exemplary embodiment;

FIG. 2 is a circuit diagram illustrating a configuration of a ring oscillator according to an exemplary embodiment of the present invention;

FIG. 3 is a circuit diagram illustrating a configuration of a current mode jitter oscillator according to an exemplary embodiment of the present invention;

FIG. 4 is a circuit diagram illustrating a configuration of a dual integrator according to an exemplary embodiment of the present invention;

FIGS. 5A and 5B are circuit diagrams illustrating examples of a switch controller of the current mode jitter oscillator, respectively;

FIG. 6 is a circuit diagram illustrating a configuration of a variable resistor using a counter, according to an exemplary embodiment of the present invention; and

FIG. 7 is a block diagram illustrating a detailed configuration of the random number signal generator of FIG. 1.

### DETAILED DESCRIPTION OF THE PREFERRED EMBODIMENT

Exemplary embodiments of the present invention will now be described in detail with reference to the accompanying drawings. Only, in describing operations of the exemplary embodiments in detail, when it is considered that a detailed description on related well-known functions or constitutions may make essential points of the present invention be unclear, the detailed description will be omitted.

A random number signal generator according to an exemplary embodiment of the present invention employs two pulse oscillators. One of the pulse oscillators is a high speed ring oscillator, the other is a current mode pulse oscillator (hereinafter, referred to as a current mode jitter oscillator) In this case, the pulse oscillators indicate oscillators generating a digital pulse by an analog or digital device.

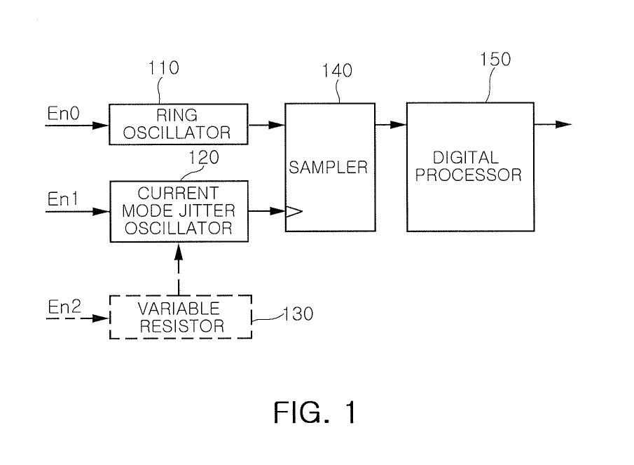

FIG. 1 is a block diagram illustrating the random number signal generator using pulse oscillators.

Referring to FIG. 1, the random number signal generator includes a ring oscillator 110, a current mode jitter oscillator 120 having a dual integrating structure, a variable resistor 130, a sampler 140, and a digital processor 150. The variable resistor 130 may be omitted according to circumstances.

The ring oscillator 110 receives an enable signal En0 as an input and generates a pulse at high speed to the sampler 140.

The current mode jitter oscillator 120 is embodied as the dual integrating structure, receives an enable signal En1 as an input, and generates a clock signal to the sampler 140

The variable resistor 130 provides a shake to a waveform of an output signal, that is, a waveform of a pulse of the current mode jitter oscillator 120 and use a resistor affected by peripheral circumstances (heat, power, and humidity) or use a device with a periodically changed resistance value may be used.

The sampler 140 includes a plurality of D flip-flops, receives an output signal of the ring oscillator 110 as data, and receives the output signal of the current mode jitter oscillator 120 as a clock signal.

The digital processor 150 is a logical circuit generating a random number by processing a random pulse generated by the sampler 140 into a data signal desired by a system. The digital processor 150 may be applied to random number signal generators of various types such as 32 bits, 64 bits, and 128 bits.

Detailed configurations of the ring oscillator 110, the current mode jitter oscillator 120, and the variable resistor 130 will be described with reference to the attached drawings.

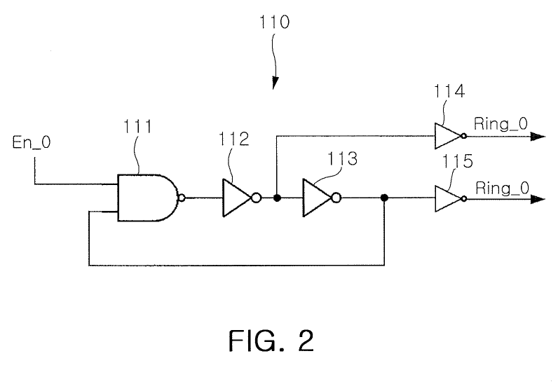

FIG. 2 is a circuit diagram illustrating a configuration of the ring oscillator 110.

The ring oscillator 110 maybe embodied as various types. However, in the present embodiment, a ring oscillator capable of being most briefly embodied will be described.

Referring to FIG. 2, the ring oscillator 110 may include one NAND gate 111 and two inverters 112 and 113. The NAND gate 111 controls a start and a stop of an oscillation and performs as an inverter when the oscillation is performed.

The ring oscillator 110 generates a first ring output signal Ring_0 and a second ring output signal Ring_1 by connecting output inverters 114 and 115 to the inverters 112 and 113, respectively. The generation of the two ring output signals Ring_0 and Ring_1 is for providing a delay of an output waveform of the ring oscillator 110.

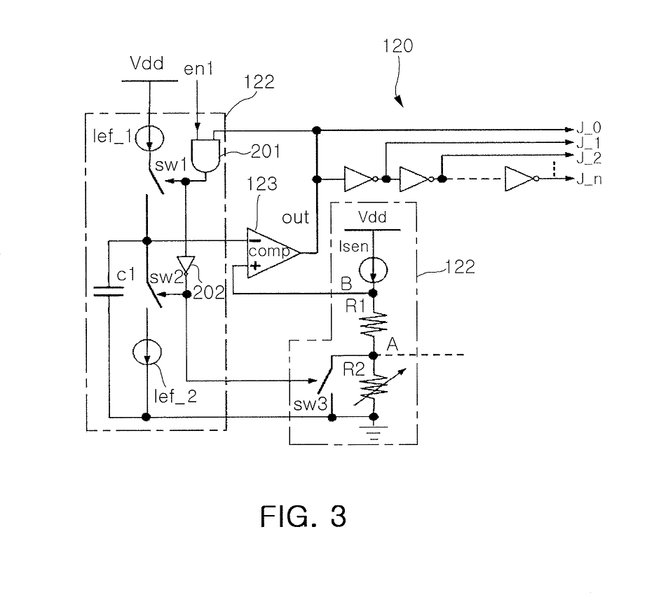

FIG. 3 is a circuit diagram illustrating a configuration of the current mode jitter oscillator 120.

Referring to FIG. 3, the current mode jitter oscillator 120 may include a dual integrator 121, a switch controller 122, and a comparator 123. Inverters for generating a plurality of output pulses J_1, J_2, , and J_n from an output signal J_0 of the comparator 123 may be connected to an output terminal of the comparator 123.

The dual integrator 121 may include current sources lef_1 and lef_2 supplying a current, a capacitor cl charging and discharging the supplied current, first and second switches sw1 and sw2 turned on/off, a logic gate 201 receiving an output signal of the switch controller 122 and turning the first and second switches sw1 and sw2 on/off, and an inverter connected between the second switch sw2 and the logic gate 201. In this case, the first and second switches sw1 and sw2 are formed of one of an n-type metal-oxide semiconductor (NMOS) and a complementary metal-oxide semiconductor (CMOS). According to circumstances, the first switch sw1 may be replaced by a p-type metal-oxide semiconductor (PMOS) and the inverter 202 may be removed. The logic gate 201 is an AND gate.

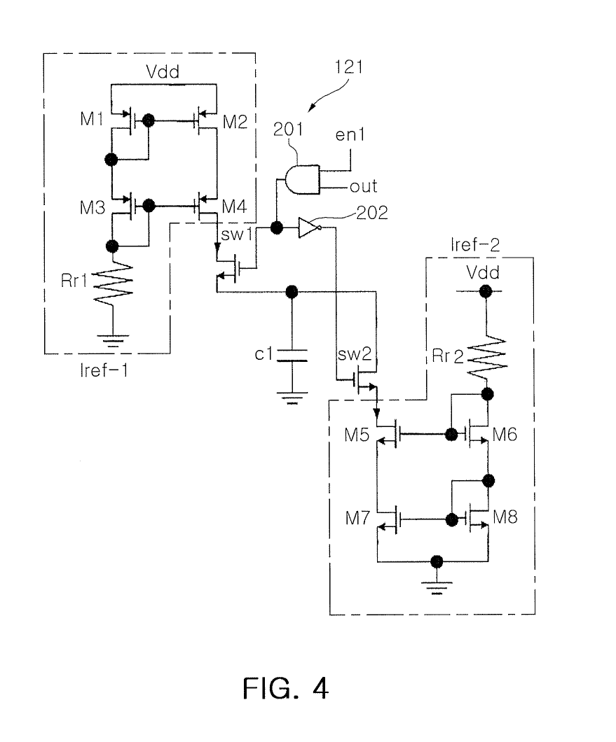

The dual integrator 121 will be described in detail with reference to FIG. 4. The current sources lef_1 and lef_2 of the dual integrator 121 may be variously embodied using metal-oxide semiconductors (MOSs) and bipolar transistors. In FIG. 4, the current sources lef_1 and lef_2 are embodied as cascade current sources 201a and 201b.

The first switch sw1 and the second switch sw2 of the dual integrator 121 are turned on/off according to an output signal of the logic gate 201 and operate opposite to each other since the inverter 202 is connected to the second switch sw2. Accordingly, when an enable signal en1 of the logic gate 201 is “1” while an output signal out is “1”, the first switch sw1 is turned on and connected to the capacitor c1. Accordingly, the second switch sw2 is turned off and a current flows into the capacitor c1, thereby increasing a voltage of the capacitor c1 and charging the current. On the other hand, when the output signal out of the logic gate 201 is “0”, the second switch sw2 is turned on and connected to the capacitor c1. Accordingly, the first switch sw1 is turned off and the current flows out from the capacitor c1, thereby reducing a charged voltage of the capacitor c1 and discharging the current.

Referring to FIG. 3, the switch controller 122 may include a current source Isen, first and second resistors R1 and R2 serially connected to the current source Isen, and a switch sw3 connected to the second resistor R2 in parallel. The switch controller 122 generates an arbitrary threshold voltage controlling the switches sw1 and sw2. By the size of a current and a resistor in the switch controller 122, a voltage B of a positive terminal of the comparator 123 is determined. By controlling the second resistor R2, a speed of an oscillation frequency of the current mode jitter oscillator 120 may be controlled. That is, the oscillation frequency is generated at high speed when a second resistance value is decreased and is generated at low speed when the second resistance value is increased.

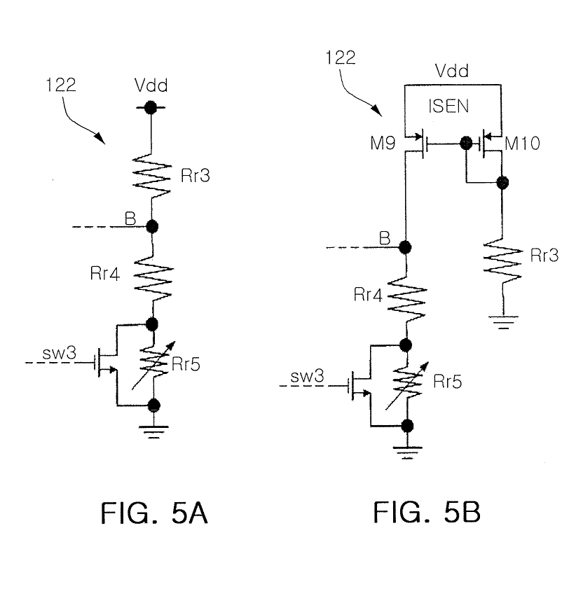

The switch controller 122 may be variously embodied as shown in FIGS. 5A and 5B Most simply, the switch controller 122 may be embodied as three serial resistors and a switch as shown in FIG. 5A and may use MOS devices as shown in FIG. 5B.

The comparator 123 receives an integrated voltage generated by the dual integrator 121 and the threshold voltage generated by the switch controller 122 as inputs, compares the integrated voltage with the threshold voltage, and generates an output pulse. In this case, the output pulse is used as an input signal to the logic gate 201 of the dual integrator 121.

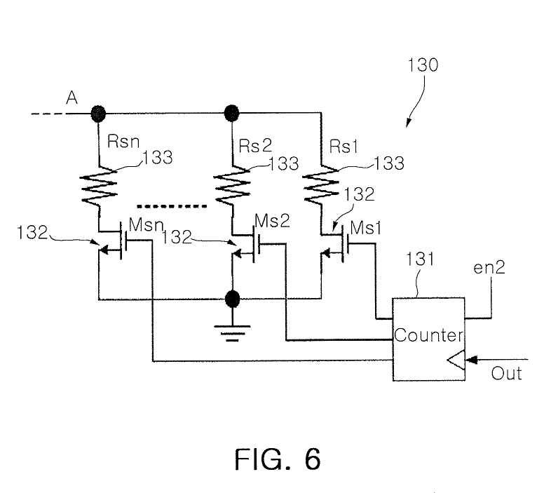

FIG. 6 is a circuit diagram illustrating the variable resistor 130.

Referring to FIG. 6, the variable resistor 130 uses a counter 131. The variable resistor 130 may be used by connecting a point A shown in FIG. 6 is connected to a point A of the current mode jitter oscillator 120 shown in FIG. 3. The variable resistor 130 includes the counter 131, a plurality of switches 132 and a plurality of resistors 133 and generates more perfect random numbers.

When an enable signal en2 is set as “1” and an output Out of the comparator 123 is connected to a clock terminal of the counter 131, an output of the counter turns the switches connected thereto, respectively, on/off. Accordingly, resistance values connected between the switches 132 and the point A are changed, thereby fluctuating an amplitude of a pulse wave. The fluctuation of the amplitude of the pulse wave may be applied to the random number signal generator.

Also, the variable resistor 130 may be embodied as one sensor resistor such as a thermal sensor.

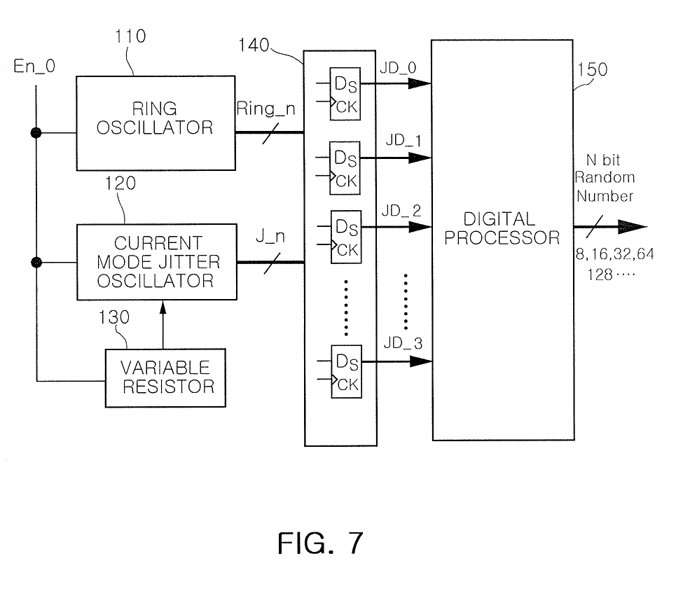

Referring to FIG. 7, the random number signal generator generates n number of random pulses JD_0, JD_1, JD_2, . . . , and JD_n by connecting two waveforms Ring_n from the ring oscillator 110 and four output waveforms J_n from the current mode jitter oscillator 120 to n number of D flip-flops of the sampler 140. In this case, the sampler 140 outputs the n number of random pulses JD_0, JD_1, JD_2, . . . , and JD_n to the digital pressor_e 150. Accordingly, the digital processor 150 generates n-bit random numbers 8, 16, 32, 64, 128, . . . desired by the system.

While the present invention has been shown and described in connection with the exemplary embodiments, it will be apparent to those skilled in the art that modifications and variations can be made without departing from the spirit and scope of the invention as defined by the appended claims.

What is claimed is:

1. A random number signal generator using pulse oscillators, the generator comprising:
a first pulse oscillator oscillating a first pulse at high speed;
a second pulse oscillator oscillating a second pulse;
a sampler inputting an output pulse of the first oscillator as data, inputting an output pulse of the second pulse oscillator as a clock signal, and outputting a plurality of output signals; and
a digital processor generating a random number signal with a desired size by using the output signals of the sampler.

2. The generator of claim 1, further comprising a variable resistor to provide a shake to a waveform of the output pulse of the second pulse oscillator.

3. The generator of claim 1, wherein the first pulse oscillator is a ring oscillator.

4. The generator of claim 3, wherein the ring oscillator comprises:
one NAND gate controlling a start and a stop of an oscillation; and
a plurality of inverters for delaying the output pulse.

5. The generator of claim 2, wherein the second pulse oscillator is a current mode jitter mode oscillator.

6. The generator of claim 5, wherein the current mode jitter oscillator comprises:
a dual integrator comprising first and second switches operating opposite to each other and charging or discharging a current according to on/off of the first and second switches;
a switch controller generating an arbitrary threshold voltage controlling the first and second switches; and
a comparator comparing an integrated voltage generated by the dual integrator with the threshold voltage generated by the switch controller.

7. The generator of claim 6, wherein the dual integrator further comprises a logic gate generating a signal for controlling the first and second switches by using an output signal and an enable signal of the comparator as an input.

8. The generator of claim 7, wherein the dual integrator further comprises an inverter operating the first and second switches opposite to each other.

9. The generator of claim 6, wherein the first switch of the dual integrator is formed of one of an n-type metal-oxide semiconductor (NMOS) and a complementary metal-oxide semiconductor (CMOS), connected to a first current source, and
the second switch of the dual integrator is formed of one of an NMOS and a CMOS, connected to a second current source.

10. The generator of claim 6, wherein the first switch of the dual integrator is formed of a p-type metal-oxide semiconductor field effect transistor (PMOS) connected to a first current source, and
the second switch of the dual integrator is formed of an NMOS connected to a second current source.

11. The generator of claim 6, wherein the current mode jitter oscillator further comprises one or more inverters generating a plurality of output pulses from the output signal of the comparator.

12. The generator of claim 6, wherein the switch controller comprises:
one or more current sources;
a resistor connected between the current source and a ground; and
a third switch connected to the resistor in parallel.

13. The generator of claim 6, wherein the switch controller comprises:
one or more first resistors;
a second resistor connected to the first resistor and a ground; and
a third switch connected to the second resistor in parallel.

14. The generator of claim 6, wherein the switch controller comprises:
one or more transistor voltage dividers;
a resistor connected between the transistor voltage divider and a ground; and
a third switch connected to the resistor in parallel.

15. The generator of claim 6, wherein the variable resistor comprises:
a counter using an output signal of the comparator as a clock and receiving an enable signal;
one or more variable resistor switches controlled according to an output signal of the counter; and
one or more resistors serially connected between the variable resistor switch and the switch controller.

16. The generator of claim 1, wherein the sampler comprises a plurality of flip-flops receiving the data and the clock signal and generating a plurality of random pulses.
